(19) United States
(12) Patent Application Publication
(10) Pub. No.: US 2026/0047448 A1
(43) Pub. Date: Feb. 12, 2026

(54) PAD, LEAD FRAME, AND SENSOR PACKAGING STRUCTURE FOR ATTENUATING EDDY CURRENT EFFECT

(71) Applicant: NINGBO CRRC TIMES TRANSDUCER TECHNOLOGY CO., LTD, Ningbo (CN)

(72) Inventors: Yang LV, Ningbo (CN); Yanan SHI, Ningbo (CN); Huaxiong ZHENG, Ningbo (CN); Mingming WU, Ningbo (CN); Liangguang ZHENG, Ningbo (CN)

(73) Assignee: NINGBO CRRC TIMES TRANSDUCER TECHNOLOGY CO., LTD, Ningbo (CN)

(21) Appl. No.: 19/360,730

(22) Filed: Oct. 16, 2025

Related U.S. Application Data
(63) Continuation of application No. PCT/CN2024/124317, filed on Oct. 12, 2024.

(30) Foreign Application Priority Data
Oct. 25, 2023 (CN) 202311386811.5

(51) Int. Cl. H01L 23/495

(52) U.S. Cl. CPC H01L 23/49541

(57) ABSTRACT

Disclosed in this disclosure are a pad, lead frame, and sensor packaging structure for attenuating an eddy current effect, which are applied to the field of semiconductor preparation. The pad includes a first pad component and a second pad component, where the first pad component and the second pad component are disposed on two adjacent sides of a chip placement region; and the first pad component and the second pad component are electrically connected, such that the first pad component and the second pad component surround the chip placement region on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor.

### CROSS-REFERENCE TO RELATED APPLICATIONS

The application claims priority to Chinese patent application No. 202311386811.5, filed on Oct. 25, 2023, the entire contents of which are incorporated herein by reference.

### TECHNICAL FIELD

This disclosure relates to the field of semiconductor preparation, and in particular, to a pad, lead frame, and sensor packaging structure for attenuating an eddy current effect.

### BACKGROUND

The Hall effect is widely used in contactless sensing fields such as current detection. However, due to the eddy current loops in the large metal of the lead frame pad, a reversed magnetic field is generated to offset the strength of the measured magnetic field, thereby weakening the detection sensitivity and accuracy of the sensor. To solve the above problem, in the prior art, a U-shaped trench is formed at the pad corresponding to the Hall device to partially interrupt the connection of the frame pad, thereby preventing the formation of the closed eddy current loops in the metal frame. However, this method has a limited effect in weakening the reversed magnetic field.

### SUMMARY

### Technical Problem

In view of this, this disclosure aims to provide a pad, lead frame, and sensor packaging structure for attenuating an eddy current effect, which solves the problem of a limited weakening effect on a reversed magnetic field in the prior art.

### Technical Solution

To solve the above technical problem, this disclosure provides a pad for attenuating an eddy current effect. The pad includes a first pad component and a second pad component, the first pad component and the second pad component are disposed on two adjacent sides of a chip placement region, and the first pad component and the second pad component are electrically connected, such that the first pad component and the second pad component surround the chip placement region on the two adjacent sides.

Optionally, one end, opposite to an end electrically connected to the second pad component, of the first pad component extends for a preset length along a preset direction; and

the preset direction is one side, close to the chip placement region, of the first pad component; and the preset length is less than a length formed by the second pad component along the preset direction.

Optionally, an extending end portion of one end, opposite to the end electrically connected to the second pad component, of the first pad component along the preset direction does not exceed one side of the chip placement region in the preset direction.

Optionally, the first pad component and the second pad component are of an integrally-formed structure. Optionally, a corner of the pad is an arc-shaped corner interface.

Optionally, the pad is provided with at least one first stress relief through hole.

This disclosure further provides a lead frame for attenuating an eddy current effect, including:
a plurality of pin components and the pad for attenuating an eddy current effect described above, where
one end, opposite to an end electrically connected to a first pad component, of a second pad component in the pad for attenuating an eddy current effect is connected to one pin.

Optionally, the plurality of pin components are provided with second stress relief through holes.

Optionally, outer sides, corresponding to the second stress relief through holes, in the plurality of pin components are provided with arc-shaped protruding structures for offsetting stresses within the second stress relief through holes.

This disclosure further provides a sensor packaging structure for attenuating an eddy current effect, including:
a chip, a package body, and the lead frame for attenuating an eddy current effect described above, where
the chip is disposed on a chip placement region in the lead frame structure; and the package body is configured to package the chip and the lead frame structure.

### Beneficial Effects

It can be seen that the pad for attenuating an eddy current effect provided by this disclosure includes the first pad component and the second pad component, the first pad component and the second pad component are disposed on the two adjacent sides of the chip placement region, and the first pad component and the second pad component are electrically connected, such that the first pad component and the second pad component surround the chip placement region on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure.

In addition, this disclosure further provides the lead frame for attenuating an eddy current effect and the sensor packaging structure for attenuating an eddy current effect, which also have the above beneficial effects.

### BRIEF DESCRIPTION OF THE DRAWINGS

To explain the technical solutions in the embodiments of this disclosure or in the prior art more clearly, the following briefly describes the accompanying drawings required for describing the embodiments or the prior art. Apparently, the accompanying drawings in the following description show only some embodiments of this disclosure, and those of ordinary skill in the art may derive other drawings from these accompanying drawings without creative efforts.

FIG. 1 is a schematic structural diagram of a pad for attenuating an eddy current effect according to an embodiment of this disclosure;

FIG. 2 is a schematic structural diagram of another pad for attenuating an eddy current effect according to an embodiment of this disclosure;

FIG. 3 is a schematic structural diagram of a lead frame for attenuating an eddy current effect according to an embodiment of this disclosure; and

FIG. 4 is a schematic structural diagram of a sensor packaging structure for attenuating an eddy current effect according to an embodiment of this disclosure.

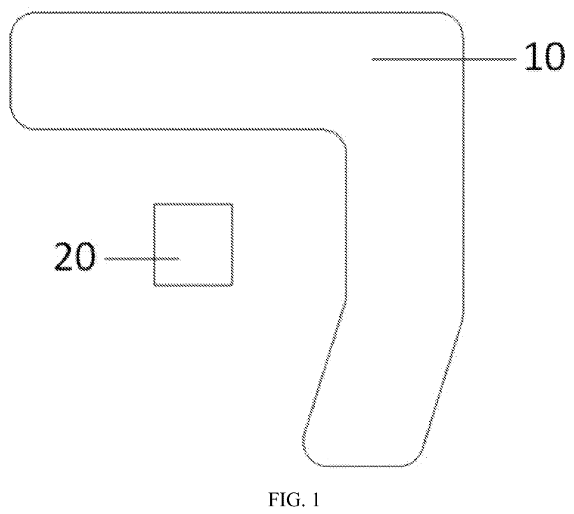

Reference numerals in FIG. 1 to FIG. 4 are as follows:
10. pad,
11. pad with one end extending outwards for a preset distance,
12. outward extending part of a pad;
20. chip placement region;
30. pin component,
31. second stress relief through hole;
40. chip;
50. lead frame component;
60. package body.

### DETAILED DESCRIPTION OF THE EMBODIMENTS

To make the objectives, technical solutions, and advantages of the embodiments of this disclosure clearer, the following clearly and completely describes the technical solutions in the embodiments of this disclosure with reference to the accompanying drawings in the embodiments of this disclosure. Apparently, the described embodiments are only some but not all of the embodiments of this disclosure. Based on the embodiments in this disclosure, all other embodiments obtained by those of ordinary skill in the art without making creative efforts shall fall within the protection scope of this disclosure.

### Embodiment 1

Referring to FIG. 1, FIG. 1 is a schematic structural diagram of a pad for attenuating an eddy current effect according to an embodiment of this disclosure. The pad 10 may include:
a first pad component and a second pad component, where the first pad component and the second pad component are disposed on two adjacent sides of a chip placement region 20, and the first pad component and the second pad component are electrically connected, such that the first pad component and the second pad component surround the chip placement region 20 on the two adjacent sides.

It needs to be noted that in this embodiment, the chip placement region 20 is configured to bear a chip, and the above chip may be of a rectangular shape or may be of other shapes. In this embodiment, two straight lines perpendicular to each other are selected along a plane where the chip placement region 20 is located to form four directions, and adjacent directions in the above four directions are perpendicular to each other. In this embodiment, the first pad component and the second pad component are disposed on the two adjacent sides of the chip placement region 20, so that the above first pad component and second pad component surround the chip placement region 20 on the two adjacent sides, and the interference of a magnetic field generated by an eddy current in the pad to the chip can be avoided. In addition, the pad is of a structure of surrounding the two adjacent sides of the chip placement region 20 by the above first pad component and second pad component, so that the support lightness and the stability of the structure can be ensured. In this embodiment, the pad has a smaller area compared with the existing pads, so that the contact area between the pad and a package material can be reduced when the structures such as the chip and the pad are packaged, thereby reducing the risk of the generation of a delamination phenomenon and improving the stability of packaging.

Specific positions for disposing the first pad component and the second pad component are not limited in this embodiment, as long as the first pad component and the second pad component are disposed on outer portions of the two adjacent sides of the chip placement region 20. For example, the first pad component and the second pad component may be disposed on an upper side of the chip placement region 20 and a right side of the chip placement region 20 respectively; or the first pad component and the second pad component may also be disposed on a left side of the chip placement region 20 and a lower side of the chip placement region 20 respectively; or the first pad component and the second pad component may further be disposed on an upper side of the chip placement region 20 and a left side of the chip placement region 20 respectively. Specific sizes of the first pad component and the second pad component are not limited in this embodiment, which may be adjusted and set according to a simulation result.

Optionally, to reduce the generation of a stress accumulation phenomenon of the pad after packaging, the above pad may be provided with at least one first stress relief through hole.

It needs to be noted that in this embodiment, the pad is provided with the stress relief through hole, so that the generation of the stress accumulation phenomenon can be reduced, and the generation of the delamination phenomenon on a contact surface between the pad and the package material can be avoided, thereby improving the stability of the structure of the pad after packaging. A specific number of the first stress relief through holes in the pad is not limited in this embodiment. For example, the pad may be provided with 1 first stress relief through hole, or the pad may also be provided with 2 first stress relief through holes. Correspondingly, a specific position of the first stress relief through hole in the pad is not limited in this embodiment, which may be arranged according to a specific size, shape, and control region of the pad. To ensure an effect of reducing stress accumulation by the first stress relief through hole, the above stress relief through hole may be formed in the pad symmetrically.

The pad 10 for attenuating an eddy current effect, including the first pad component and the second pad component, provided by this embodiment of this disclosure is applied. The first pad component and the second pad component are disposed on the two adjacent sides of the chip placement region 20, and the first pad component and the second pad component are electrically connected, such that the first pad component and the second pad component surround the chip placement region 20 on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure. In addition, in this embodiment of this disclosure, the pad is provided with at least one first stress relief through hole, so that the generation of the stress accumulation phenomenon of the pad after packaging can be further avoided, thereby improving the stability of the structure of the pad after packaging.

### Embodiment 2

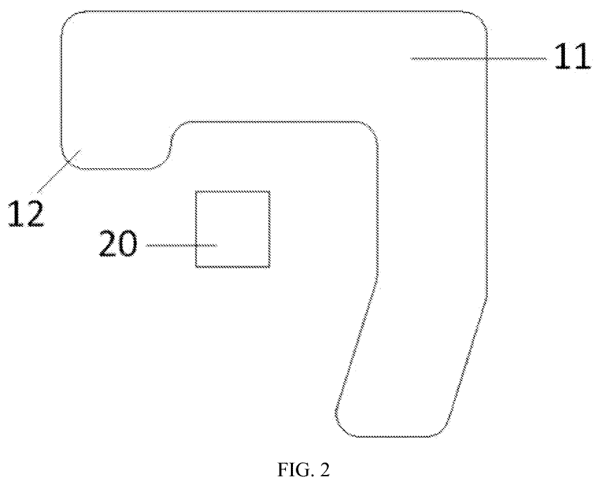

Referring to FIG. 2, FIG. 2 is a schematic structural diagram of another pad for attenuating an eddy current effect according to an embodiment of this disclosure. The pad may include:
a first pad component and a second pad component, where the first pad component and the second pad component are disposed on two adjacent sides of a chip placement region 20, and the first pad component and the second pad component are electrically connected, such that the first pad component and the second pad component surround the chip placement region 20 on the two adjacent sides;
one end, opposite to an end electrically connected to the second pad component, of the first pad component extends for a preset length along a preset direction; and the preset direction is one side, close to the chip placement region 20, of the first pad component; and the preset length is less than a length formed by the second pad component along the preset direction.

It needs to be noted that in this embodiment, one end, opposite to the end electrically connected to the second pad component, of the first pad component, that is, one end, away from the end electrically connected to the second pad component, in an extending direction of the first pad component extends outwards for the preset length on one side, close to the chip placement region 20, of the first pad component, and the preset length is less than the length formed by the second pad component along the preset direction, so that a magnetic field generated by an eddy current due to an excessively large pad area can be prevented from affecting the accuracy of a chip in detecting an external magnetic field while improving the support strength of the pad and the stability of the structure. A specific value of the preset length is not limited in this embodiment, which may be adjusted and set according to a simulation result. It needs to be further noted that in this embodiment, the pad 11 with one end extending outwards for a preset distance, that is, a pad obtained after one end, away from the end electrically connected to the second pad component, in the extending direction of the first pad component extends outwards for the preset length on one side, close to the chip placement region 20, of the first pad component, and the preset length is less than the length formed by the second pad component along the preset direction. A structure extended from the pad may refer to an outward extending part 12 of the pad in FIG. 2.

Further, to reduce the impact of the outward extending structure of one end, away from the end electrically connected to the second pad component, in the extending direction of the first pad component on one side, close to the chip placement region 20, of the first pad component on chip magnetic field detection, an extending end portion of one end, opposite to the end electrically connected to the second pad component, of the first pad component along the preset direction does not exceed one side of the chip placement region 20 in the preset direction.

It needs to be noted that in this embodiment, the outward extending end portion of the first pad component does not exceed an edge position on one side of the chip placement region 20 in the preset direction, so that the structure extending from the first pad component can be prevented from surrounding the chip placement region 20, thereby reducing the impact of the generated magnetic field on the chip in detecting the external magnetic field while improving the structural strength of the pad.

The pad for attenuating an eddy current effect, including the first pad component and the second pad component, provided by this embodiment of this disclosure is applied. The first pad component and the second pad component are disposed on the two adjacent sides of the chip placement region 20, and the first pad component and the second pad component are electrically connected, such that the first pad component and the second pad component surround the chip placement region 20 on the two adjacent sides. One end, opposite to the end electrically connected to the second pad component, of the first pad component extends for the preset length along the preset direction. The preset direction is one side, close to the chip placement region 20, of the first pad component, and the preset length is less than the length formed by the second pad component along the preset direction. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure. By means of extending the first pad component outwards for the preset length on one side, close to the chip placement region 20, of the first pad component, the support strength of the pad and the stability of the structure can be improved. In addition, in this embodiment of this disclosure, the outward extending end portion of the first pad component does not exceed the edge position on one side of the chip placement region 20 in the preset direction, so that the structure extending from the first pad component can be prevented from surrounding the chip placement region 20, thereby reducing the impact of the generated magnetic field on the chip in detecting the external magnetic field while improving the structural strength of the pad.

### Embodiment 3

Referring to FIG. 1, FIG. 1 is a schematic structural diagram of a pad for attenuating an eddy current effect according to an embodiment of this disclosure.

The pad may include:
a first pad component and a second pad component, where the first pad component and the second pad component are disposed on two adjacent sides of a chip placement region 20, and the first pad component and the second pad component are electrically connected, such that the first pad component and the second pad component surround the chip placement region 20 on the two adjacent sides; and
the first pad component and the second pad component are of an integrally-formed structure.

It needs to be noted that in this embodiment, the first pad component and the second pad component are of the integrally-formed structure, so that the stability of the structure of the pad can be ensured, thereby further improving the support strength of the pad.

Further, to reduce the stress accumulation of a contact surface between the pad and a package material after packaging, a corner of the above pad may be an arc-shaped corner interface.

It needs to be noted that in this embodiment, the corner of the pad is the arc-shaped corner interface, so that the stress accumulation generated after packaging can be further reduced, the stability of the structure of the pad after packaging can be improved, and the generation of a delamination phenomenon can be avoided.

The pad for attenuating an eddy current effect, including the first pad component and the second pad component, provided by this embodiment of this disclosure is applied. The first pad component and the second pad component are disposed on the two adjacent sides of the chip placement region 20, and the first pad component and the second pad component are electrically connected, such that the first pad component and the second pad component surround the chip placement region 20 on the two adjacent sides. The first pad component and the second pad component are of the integrally-formed structure. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of the delamination phenomenon, and improving the stability of the structure. The first pad component and the second pad component are of the integrally-formed structure, so that the stability of the structure of the pad can be ensured, thereby further improving the support strength of the pad. In addition, in this embodiment of this disclosure, the corner of the pad is the arc-shaped corner interface, so that the stress accumulation generated after packaging can be further reduced, the stability of the structure of the pad after packaging can be improved, and the generation of the delamination phenomenon can be avoided.

For ease of understanding of the pad for attenuating an eddy current effect provided by this disclosure, the above pad for attenuating an eddy current effect may include:
the first pad component and the second pad component, where the first pad component and the second pad component are disposed on the two adjacent sides of the chip placement region, and the first pad component and the second pad component are electrically connected, such that the first pad component and the second pad component surround the chip placement region on the two adjacent sides;
one end, opposite to an end electrically connected to the second pad component, of the first pad component extends along a preset direction; the preset direction is one side, close to the chip placement region, of the first pad component; and an extending end portion of one end, opposite to the end electrically connected to the second pad component, of the first pad component along the preset direction does not exceed one side of the chip placement region in the preset direction; and
the first pad component and the second pad component are of the integrally-formed structure; the corner of the pad is the arc-shaped corner interface; and the pad is provided with at least one first stress relief through hole.

The following introduces a lead frame for attenuating an eddy current effect provided by an embodiment of this disclosure, and the lead frame for attenuating an eddy current effect described below and the pad for attenuating an eddy current effect described above may refer to each other.

### Embodiment 4

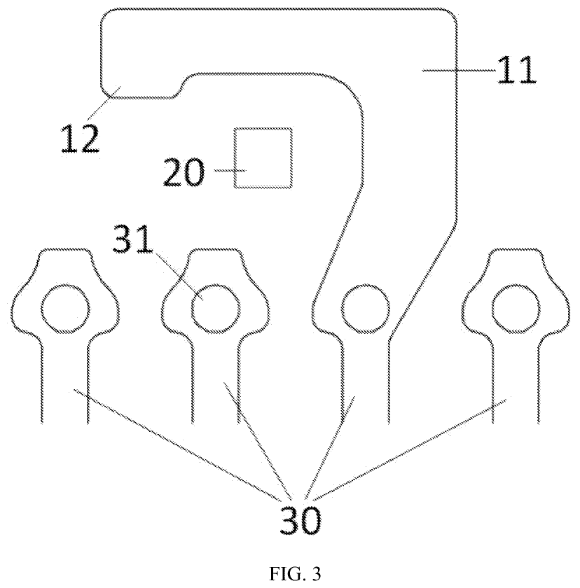

Specifically, referring to FIG. 3, FIG. 3 is a schematic structural diagram of a lead frame for attenuating an eddy current effect according to an embodiment of this disclosure. The lead frame may include:
a plurality of pin components 30 and the pad 10 for attenuating an eddy current effect described above, where
one end, opposite to an end electrically connected to a first pad component, of a second pad component in the pad 10 for attenuating an eddy current effect is connected to one pin.

It needs to be noted that in this embodiment, the lead frame includes the above pad 10 for attenuating an eddy current effect and a plurality of pins, and one of the pins is electrically connected to the pad 10, to implement the functionality of the lead frame. A specific number of the plurality of pin components 30 is not limited in this embodiment, which may be set according to a function of the lead frame. Similarly, specific structures of the plurality of pin components 30 are not limited in this embodiment. In this embodiment, a position, close to the bottom pin component, of the second pad components is structured to incline toward the pin components, which may be adaptively adjusted according to a specific application scenario, to facilitate the connection between the pad 11 and the pin components.

It needs to be further noted that in this embodiment, a lead frame component 50 may further be included, to ensure the structural strength and stability of the lead frame.

The lead frame for attenuating an eddy current effect, including the plurality of pin components 30 and the pad 10 for attenuating an eddy current effect described above, provided by this embodiment of this disclosure is applied. One end, opposite to the end connected to the first pad component, of the second pad component in the pad 10 for attenuating an eddy current effect is connected to one pin. The pad 10 for attenuating an eddy current effect includes the first pad component and the second pad component. The first pad component and the second pad component are disposed on the two adjacent sides of the chip placement region 20, and the first pad component and the second pad component are electrically connected, such that the first pad component and the second pad component surround the chip placement region 20 on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure.

### Embodiment 5

Specifically, referring to FIG. 3, FIG. 3 is a schematic structural diagram of a lead frame for attenuating an eddy current effect according to an embodiment of this disclosure. The lead frame may include:
a plurality of pin components 30 and the pad 10 for attenuating an eddy current effect described above, where
one end, opposite to an end electrically connected to a first pad component, of a second pad component in the pad 10 for attenuating an eddy current effect is connected to one pin; and
the plurality of pin components 30 are provided with second stress relief through holes 31.

It needs to be noted that in this embodiment, the plurality of pin components 30 are provided with the second stress relief through holes 31, so that the internal stress accumulation of the lead frame after packaging can be further reduced, and the stability of the lead frame after packaging can be improved.

Further, to reduce the internal stress accumulation of the lead frame after packaging, outer sides, corresponding to the second stress relief through holes 31, in the plurality of pin components 30 are provided with arc-shaped protruding structures for offsetting stresses within the second stress relief through holes 31.

It needs to be noted that in this embodiment, the arc-shaped protruding structures for offsetting the stresses are formed corresponding to the second stress relief through holes 31 in the plurality of pin components 30, so that the stress generated after the lead frame is packaged can be further reduced while avoiding intrusion of water vapor along a packaging interface after the lead frame is packaged, thereby improving the good rate of a product. A specific shape of the arc-shaped protruding structure is not limited in this embodiment, which may be set according to a simulation result.

The lead frame for attenuating an eddy current effect, including the plurality of pin components 30 and the pad 10 for attenuating an eddy current effect described above, provided by this embodiment of this disclosure is applied. One end, opposite to the end connected to the first pad component, of the second pad component in the pad 10 for attenuating an eddy current effect is connected to one pin. The plurality of pin components 30 are provided with the second stress relief through holes 31. The pad 10 for attenuating an eddy current effect includes the first pad component and the second pad component. The first pad component and the second pad component are disposed on the two adjacent sides of the chip placement region 20, and the first pad component and the second pad component are electrically connected, such that the first pad component and the second pad component surround the chip placement region 20 on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure. By means of forming the second stress relief through holes 31 in the plurality of pin components 30, the internal stress accumulation of the lead frame after packaging can be further reduced, and the stability of the lead frame after packaging can be improved. In addition, in this embodiment of this disclosure, the arc-shaped protruding structures for offsetting the stresses are formed corresponding to the second stress relief through holes 31 in the plurality of pin components 30, so that the stress generated after the lead frame is packaged can be further reduced while avoiding intrusion of water vapor along a packaging interface after the lead frame is packaged, thereby improving the good rate of the product.

The following introduces a sensor packaging structure for attenuating an eddy current effect provided by an embodiment of this disclosure, and the sensor packaging structure for attenuating an eddy current effect described below and the lead frame for attenuating an eddy current effect described above may refer to each other.

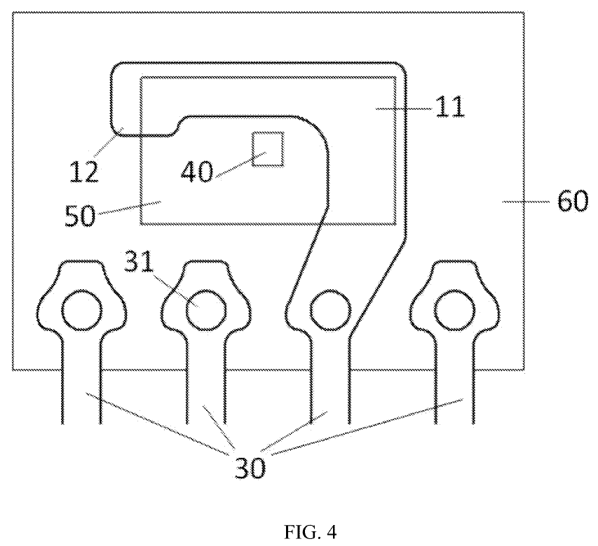

Referring to FIG. 4, FIG. 4 is a schematic structural diagram of a sensor packaging structure for attenuating an eddy current effect according to an embodiment of this disclosure. The sensor packaging structure may include:
a chip 40, a package body 60, and the lead frame for attenuating an eddy current effect described above, where
the chip 40 is disposed on a chip placement region in the lead frame structure; and
the package body 60 is configured to package the chip 40 and the lead frame structure.

It needs to be noted that in this embodiment, the package body 60 is utilized to package the chip 40 and the lead frame structure, thereby protecting the lead frame and the chip 40 and ensuring stable operations of the product. A specific material of the package body 60 is not limited in this embodiment, which may be selected according to an application scenario.

The sensor packaging structure for attenuating an eddy current effect, including the chip 40, the package body 60, and the lead frame for attenuating an eddy current effect described above, provided by this embodiment of this disclosure is applied. The chip 40 is disposed on the chip placement region in the lead frame structure, and the package body 60 is configured to package the chip 40 and the lead frame structure. The lead frame for attenuating an eddy current effect includes the plurality of pin components 30 and the pad 10 for attenuating an eddy current effect. One end, opposite to the end electrically connected to the first pad component, of the second pad component in the pad 10 for attenuating an eddy current effect is connected to one pin. The pad 10 for attenuating an eddy current effect includes the first pad component and the second pad component. The first pad component and the second pad component are disposed on the two adjacent sides of the chip placement region, and the first pad component and the second pad component are electrically connected, such that the first pad component and the second pad component surround the chip placement region on the two adjacent sides. In this disclosure, by means of arranging the pad along two adjacent sides of a chip, the formation of closed eddy current loops in a metal frame can be further reduced, thereby weakening the impact of a reversed magnetic field, and thus improving the detection sensitivity and accuracy of a sensor; in addition, by means of reducing the area of a metal pad, the contact area between the chip and a plastic package body is increased when the chip is packaged, thus reducing the stress generated by the structure, avoiding the generation of a delamination phenomenon, and improving the stability of the structure.

Various embodiments in the specification are described in a progressive manner, and each embodiment focuses on the differences from the other embodiments, and the same or similar parts between the various embodiments can refer to each other. The apparatus disclosed in the embodiments is described relatively simply because it corresponds to the method disclosed in the embodiments, and for portions related to those of the method, reference may be made to the description of the method.

Finally, it needs to further be noted that relational terms herein, such as first and second, are only used to distinguish one entity or operation from another entity or operation, and do not necessarily require or imply any such actual relationship or order among these entities or operations. Moreover, the terms “include”, “comprise”, or any other variants thereof are intended to cover non-exclusive inclusion, so that a process, method, item, or apparatus including a series of elements includes not only those elements but also other elements not explicitly listed, or further includes inherent elements of such process, method, item, or apparatus.

A pad, lead frame, and sensor packaging structure for attenuating an eddy current effect provided by this disclosure are introduced in detail above. The principle and implementations of this disclosure are described in this specification through specific examples. The descriptions about the embodiments are merely provided to help understand the methods and core ideas of this disclosure. In addition, those of ordinary skill in the art can make variations to the specific implementations and application scopes according to the ideas of this disclosure. In summary, the content of this specification shall not be construed as any limitation to this disclosure.

What is claimed is:

1. A pad for attenuating an eddy current effect, wherein the pad comprises a first pad component and a second pad component, the first pad component and the second pad component are disposed on two adjacent sides of a chip placement region, and the first pad component and the second pad component are electrically connected, such that the first pad component and the second pad component surround the chip placement region on the two adjacent sides;
one end, opposite to an end electrically connected to the second pad component, of the first pad component extends for a preset length along a preset direction; and
the preset direction is one side, close to the chip placement region, of the first pad component; the preset length is less than a length formed by the second pad component along the preset direction; and an extending end portion of one end, opposite to the end electrically connected to the second pad component, of the first pad component along the preset direction does not exceed one side of the chip placement region in the preset direction.

2. The pad for attenuating an eddy current effect according to claim 1, wherein the first pad component and the second pad component are of an integrally-formed structure.

3. The pad for attenuating an eddy current effect according to claim 1, wherein a corner of the pad is an arc-shaped corner interface.

4. The pad for attenuating an eddy current effect according to claim 1, wherein the pad is provided with at least one first stress relief through hole.

5. A lead frame for attenuating an eddy current effect, comprising:
a plurality of pin components and the pad for attenuating an eddy current effect according to claim 1, wherein
one end, opposite to an end electrically connected to a first pad component, of a second pad component in the pad for attenuating an eddy current effect is connected to one pin.

6. The lead frame for attenuating an eddy current effect according to claim 5, wherein the plurality of pin components are provided with second stress relief through holes.

7. The lead frame for attenuating an eddy current effect according to claim 6, wherein outer sides, corresponding to the second stress relief through holes, in the plurality of pin components are provided with arc-shaped protruding structures for offsetting stresses within the second stress relief through holes.

8. A sensor packaging structure for attenuating an eddy current effect, comprising:
a chip, a package body, and the lead frame for attenuating an eddy current effect according to claim 5, wherein
the chip is disposed on a chip placement region in the lead frame structure; and
the package body is configured to package the chip and the lead frame structure.
